(19) United States
(12) Patent Application Publication
(10) Pub. No.: US 2008/0054272 A1
(43) Pub. Date: Mar. 6, 2008

(54) Semiconductor light-emitting device and method of manufacturing the same

(75) Inventors: Nobuya Sato, Miyagi (JP); Kazunari Saitou, Miyagi (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 11/896,682

(22) Filed: Sep. 5, 2007

(30) Foreign Application Priority Data
Sep. 6, 2006 (JP) 2006-241410

(51) Int. Cl. H01L 33/00; H01L 21/02

(52) U.S. Cl. 257/79; 438/33; 257/E21.002; 257/E33.001

(57) ABSTRACT

A semiconductor light-emitting device capable of preventing fusion bonding between electrodes or damage to an electrode, and a method of manufacturing the same are provided. A semiconductor light-emitting device includes a semiconductor layer and a first electrode on a first surface of a semiconductor substrate in order from the semiconductor substrate side and a second electrode on a second surface of the semiconductor substrate, the semiconductor layer including a light-emitting region, the first electrode being arranged corresponding to at least the light-emitting region, wherein a recessed section with a depth larger than the thickness of the second electrode in arranged on the second surface, thereby a step section projected from the recessed section is formed in a region other than the recessed section in the second surface, and the second electrode is formed on a least the recessed section of the second surface.

### CROSS REFERENCES TO RELATED APPLICATIONS

The present invention contains subject matter related to Japanese Patent Application JP 2006-241410 filed in the Japanese Patent Office on Sep. 6, 2006, the entire contents of which being incorporated herein by reference.

### BACKGROUND OF THE INVENTION

1. Field of the Invention

The present invention relates to a semiconductor light-emitting device including a semiconductor layer and a first electrode on one surface of a substrate and a second electrode on the other surface of the substrate, and a method of manufacturing the semiconductor light-emitting device.

2. Description of the Related Art

A coating film is formed on an end surface of a laser diode to prevent oxidation and adhesion of contamination and control reflectivity. For example, as shown in FIG. 21, an n-type cladding layer 121, an active layer 122, a p-type cladding layer 123, a p-side contact layer 124 and a p-side electrode 130 are formed on one surface of a substrate and an n-side electrode 140 is formed on the other surface of the substrate, and they are cut to form a plurality of LD (laser diode) bars, and then such a coating film on the end surface is formed by evaporation in a state in which the LD bars are stacked. The evaporation takes place on condition that the temperature of the LD bars is 260° C., so in a state in which the p-side electrode 130 and the n-side electrode 140 are in contact with each other, the electrodes may be fusion bonded to each other. To prevent this, in related arts, for example, as shown in FIG. 22, evaporation takes place in a state in which a silicon (Si) chip 160 as a dummy bar is inserted between LD bars (for example, refer to Japanese Unexamined Patent Application Publication No. H10-93187).

### SUMMARY OF THE INVENTION

However, in the above-described method in related arts, there is an issue such as low workability, or easily damaging or contaminating the electrodes.

In view of the foregoing, it is desirable to provide a semiconductor light-emitting device capable of preventing fusion bonding between electrodes and damage to electrodes, and a method of manufacturing the semiconductor light-emitting device.

According to an embodiment of the invention, there is provided a semiconductor light-emitting device including a semiconductor layer and a first electrode on a first surface of a semiconductor substrate in order from the semiconductor substrate side and a second electrode on a second surface of the semiconductor substrate, the semiconductor layer including a light-emitting region, the first electrode being arranged corresponding to at least the light-emitting region, wherein a recessed section with a depth larger than the thickness of the second electrode is arranged on the second surface, thereby a step section projected from the recessed section is formed in a region other than the recessed section in the second surface, and the second electrode is formed on at least the recessed section of the second surface.

Here, “a recessed section” is not limited to a section surrounded by a step section such as a groove or a hole, and includes, for example, the case where a columnar-shaped or ridge-shaped step section is surrounded by a planar section, and the top surface of the planar section is positioned lower than the top surface of the step section as a concept.

According to an embodiment of the invention, there is provided a method of manufacturing a semiconductor light-emitting device, the semiconductor light-emitting device including a semiconductor layer and a first electrode on a first surface of a semiconductor substrate and a second electrode on a second surface of the semiconductor substrate, the semiconductor layer including a light-emitting region, the method comprising the steps of after forming the semiconductor layer on the first surface, forming the first electrode on the first surface so as to correspond to at least the light-emitting region; arranging a recessed section with a depth larger than the thickness of the second electrode on the second surface so as to form a step section projected from the recessed section in a region other than the recessed section in the second surface; forming the second electrode on at least the recessed section of the second surface; forming a plurality of bars by cutting the semiconductor substrate; and stacking the plurality of bars so that the first electrode and the second electrode face each other, and forming a coating film on a cutting surface.

In the semiconductor light-emitting device according to the embodiment of the invention or the method of manufacturing a semiconductor light-emitting device according to the embodiment of the invention, a recessed section with a depth larger than the thickness of the second electrode is arranged on the second surface of the semiconductor substrate, and the second electrode is formed on the recessed section, so in the case where a plurality of bars are stacked, contact between the first electrode and the second electrode can be prevented, thereby fusion bonding between electrodes or damage to electrodes can be prevented.

Other and further objects, features and advantages of the invention will appear more fully from the following description.

### BRIEF DESCRIPTION OF THE DRAWINGS

FIG. 1 is a sectional view showing the configuration of a laser diode according to a first embodiment of the invention;

FIG. 2 is a plan view showing the configuration of the laser diode shown in FIG. 1 when viewed from an n-side electrode side;

FIG. 3 is a sectional view showing a step in a method of manufacturing the laser diode shown in FIG. 1;

FIG. 4 is a sectional view showing a step following the step of FIG. 3;

FIG. 5 is a sectional view showing a step following the step of FIG. 4;

FIG. 6 is a sectional view showing a step following the step of FIG. 5;

FIG. 7 is a sectional view showing a modification of a p-side electrode and an n-side electrode of the laser diode shown in FIG. 1;

FIG. 8 is a plan view showing Modification 1 of the invention;

FIG. 9 is a plan view showing Modification 2 of the invention;

FIG. 10 is a plan view showing Modification 3 of the invention;

FIG. 11 is a plan view showing Modification 4 of the invention;

FIG. 12 is a plan view showing Modification 5 of the invention;

FIG. 13 is a plan view showing Modification 6 of the invention;

FIG. 14 is a sectional view showing the configuration of a laser diode according to a second embodiment of the invention;

FIG. 15 is a sectional view showing a modification of a p-side electrode and an n-side electrode of the laser diode shown in FIG. 14;

FIG. 16 is a sectional view showing the configuration of a laser diode according to a third embodiment of the invention;

FIG. 17 is a sectional view showing a modification of a p-side electrode and an n-side electrode of the laser diode shown in FIG. 16;

FIG. 18 is a plan view showing a modification of the laser diode shown in FIG. 2;

FIG. 19 is a plan view showing another modification of the laser diode shown in FIG. 2;

FIG. 20 is a sectional view showing still another modification of the laser diode shown in FIG. 2;

FIG. 21 is a sectional view for describing a method of manufacturing a laser diode in related arts; and

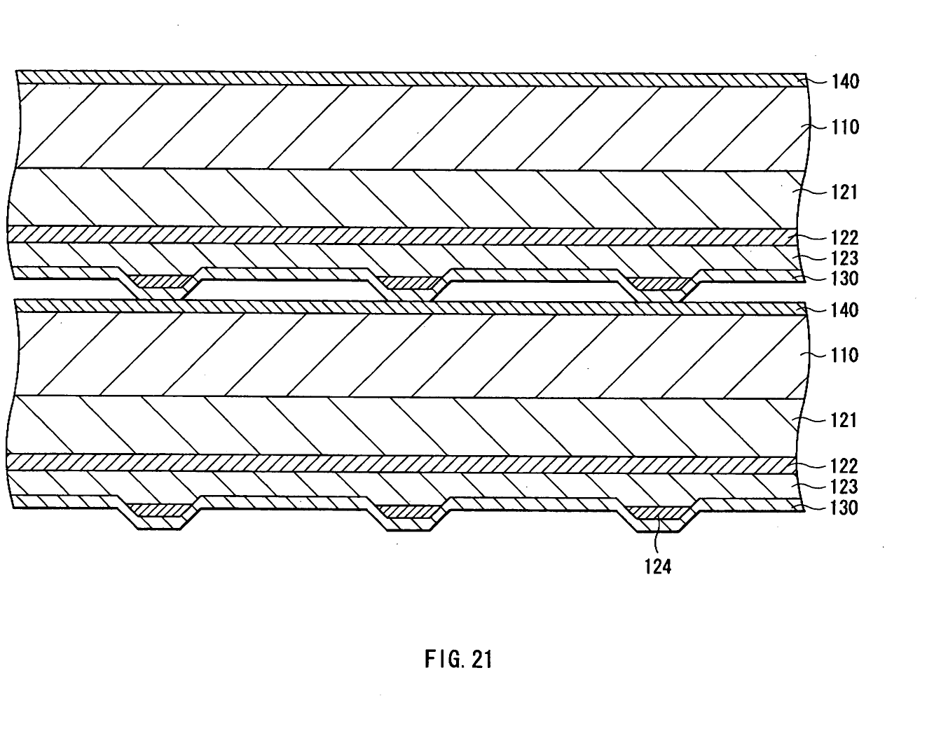

FIG. 22 is a sectional view for describing another method of manufacturing a laser diode in related arts.

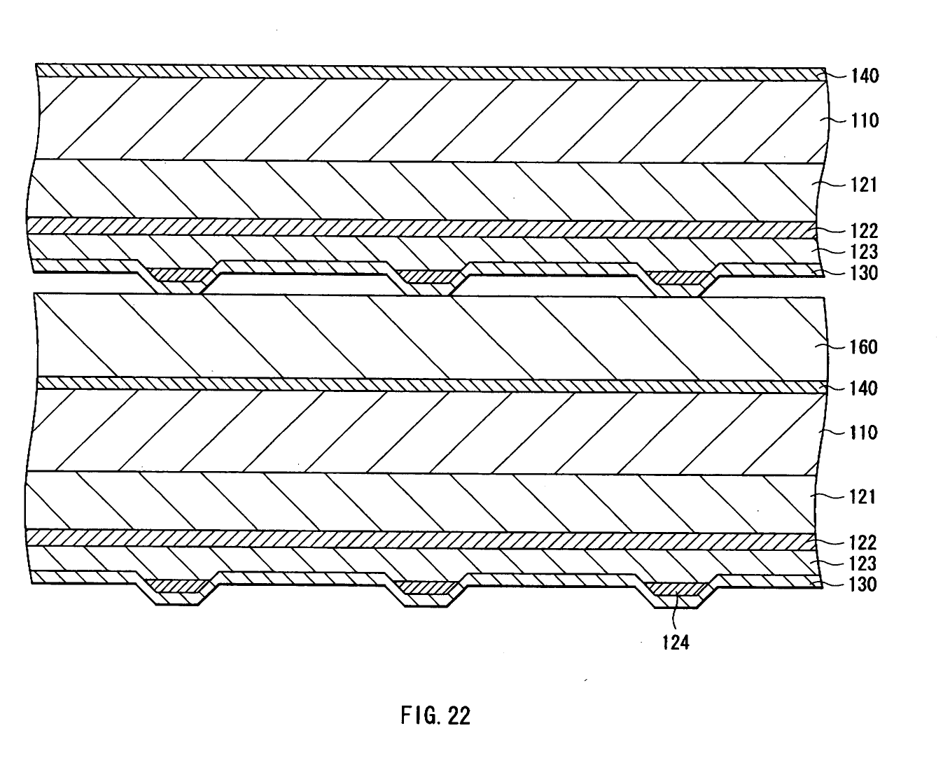

### DETAILED DESCRIPTION OF THE PREFERRED EMBODIMENTS

Preferred embodiments will be described in detail below referring to the accompanying drawings.

### First Embodiment

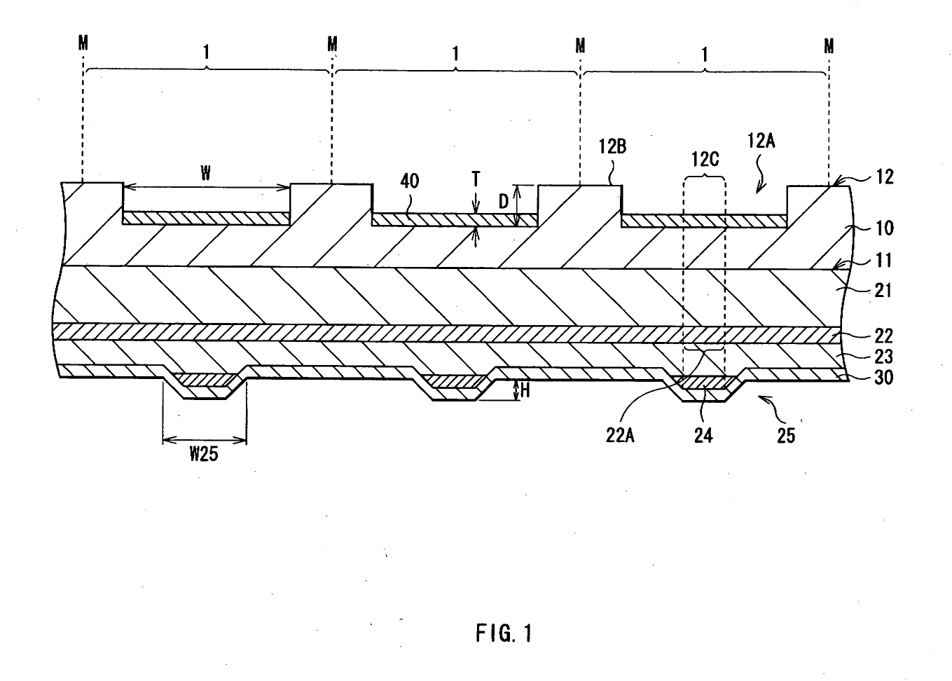

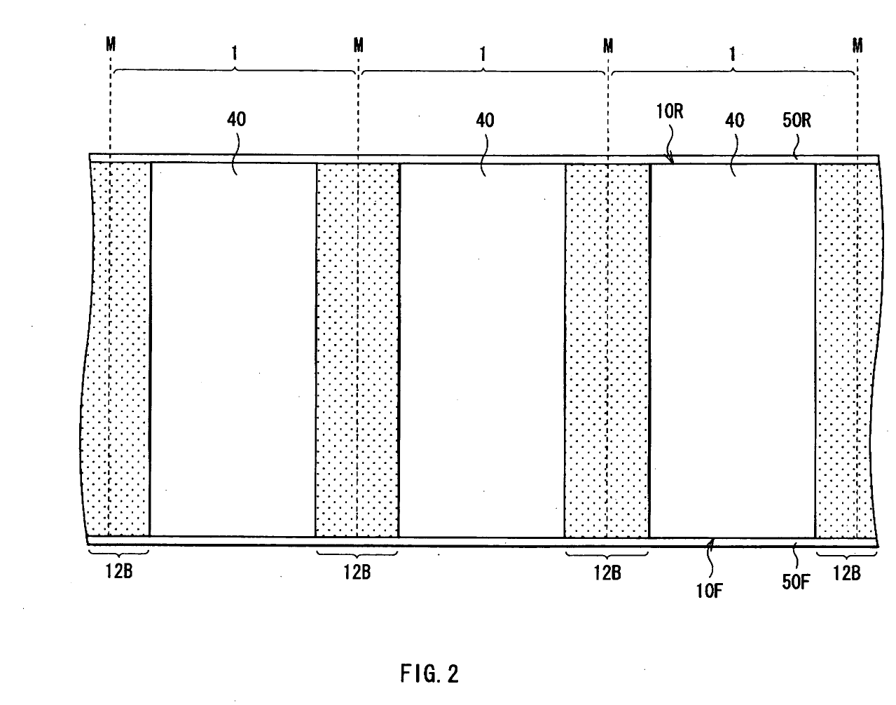

FIGS. 1 and 2 show the configuration of a laser diode according to a first embodiment of the invention. The laser diode is used, for example, in a DVD (Digital Versatile Disc) player, and the laser diode is an LD bar in which a plurality of chip regions 1 are arranged together. Each chip region 1 has, for example, a configuration in which an n-type cladding layer 21, an active layer 22, a p-type cladding layer 23 and a p-side contact layer 24 are laminated in this order on a first surface 11 of a substrate 10.

The substrate 10 is made of, for example, n-type GaAs doped with an n-type impurity such as silicon (Si) or selenium (Se). The n-type cladding layer 21 has a thickness in a laminating direction (hereinafter simply referred to as “thickness”) of 1.4 μm, and is made of n-type (Al_{0.70}Ga_{0.3})_{0.5}In_{0.5}P mixed crystal doped with an n-type impurity such as silicon or selenium. The active layer 22 has, for example, a thickness of 30 nm, and has a multiquantum well structure in which GaInP mixed crystal layers and AlGaInP mixed crystal layers are laminated alternately. The p-type cladding layer 23 has, for example, a thickness of 1.3 μm, and is made of p-type (Al_{0.70}Ga_{0.3})_{0.5}In_{0.5}P mixed crystal doped with a p-type impurity such as zinc or magnesium. The p-side contact layer 24 has, for example, a thickness of 0.3 μm, and is made of p-type GaAs doped with a p-type impurity such as zinc or magnesium.

The p-side contact layer 24 and the p-type cladding layer 23 are partially removed by etching to form a thin strip-shaped projection section (ridge) 25, and a region corresponding to the projection section 25 in the active layer 22 is a light-emitting region (current injection region) 22A.

A p-side electrode 30 is formed on a surface of the p-side contact layer 24 with an insulating film (not shown) made of silicon dioxide in between. For example, the p-side electrode 30 has a configuration in which titanium (Ti), platinum (Pt) and gold (Au) are laminated in order, and is arranged on the whole surfaces of the p-side contact layer 24 and the insulating film, and the p-side electrode 30 is electrically connected to the p-side contact layer 24 through an opening (not shown) arranged in the insulating film.

A recessed section 12A is arranged on the second surface 12 of the substrate 10, and a region other than the recessed section 12A is a step section 12B projected from the recessed section 12A. An n-side electrode 40 is formed inside the recessed section 12A, for example, on a bottom surface of the recessed section 12A. Therefore, in the laser diode, in the case where LD bars are stacked, the step section 12B acts as a spacer, so fusion bonding between the n-side electrode 40 and the p-side electrode 30 or damage to the n-side electrode 40 and the p-side electrode 30 can be prevented.

The depth D of the recessed section 12A is larger than the thickness T of the n-side electrode 40. Moreover, the depth D of the recessed section 12A is more preferably larger than the total of the thickness T of the n-side electrode 40 and the height H of a step formed by the projection section 25 and the p-side electrode 30. However, when the recessed section 12A has a too large depth, cleavage precision may decline, or it may be difficult to mount the laser diode in a package, so, for example, the depth D of the recessed section 12A is preferably approximately a few μm. Further, the width W of the recessed section 12A is preferably larger than the width W25 of the projection section 25.

The step section 12B is preferably arranged on a boundary line M of adjacent chip regions 1 and not on a region 12C facing the light-emitting region 22A in the second surface 12. It is because in the case where the LD bars are stacked, the p-side electrode 30 on the light-emitting region 22A can be prevented from being damaged by contact with the step section 12B.

The n-side electrode 40 has, for example, a configuration in which AuGe:Ni and gold (Au) are laminated in order, and are alloyed by a heat treatment, and the n-side electrode 40 is electrically connected to the substrate 10. The n-side electrode 40 may be formed on not only the bottom surface of the recessed section 12A but also a side surface or a part of a side surface of the recessed section 12A.

Further, in the laser diode, a main-emission-side end surface 10F and a rear end surface 10R which face each other in a resonator direction are a pair of resonator end surfaces. Coating films 50F and 50R as a pair of reflecting mirror films are formed on the main-emission-side end surface 10F and the rear end surface 10R, respectively, and the coating film 50F is adjusted so as to have low reflectivity, and the coating film 50R is adjusted so as to have high reflectivity. Thereby, light emitted from the active layer 22 travels between the coating films 50F and 50R so as to be amplified, and the amplified light is emitted from the coating film 50F with low reflectivity as a laser beam.

For example, the laser diode can be manufactured by the following steps.

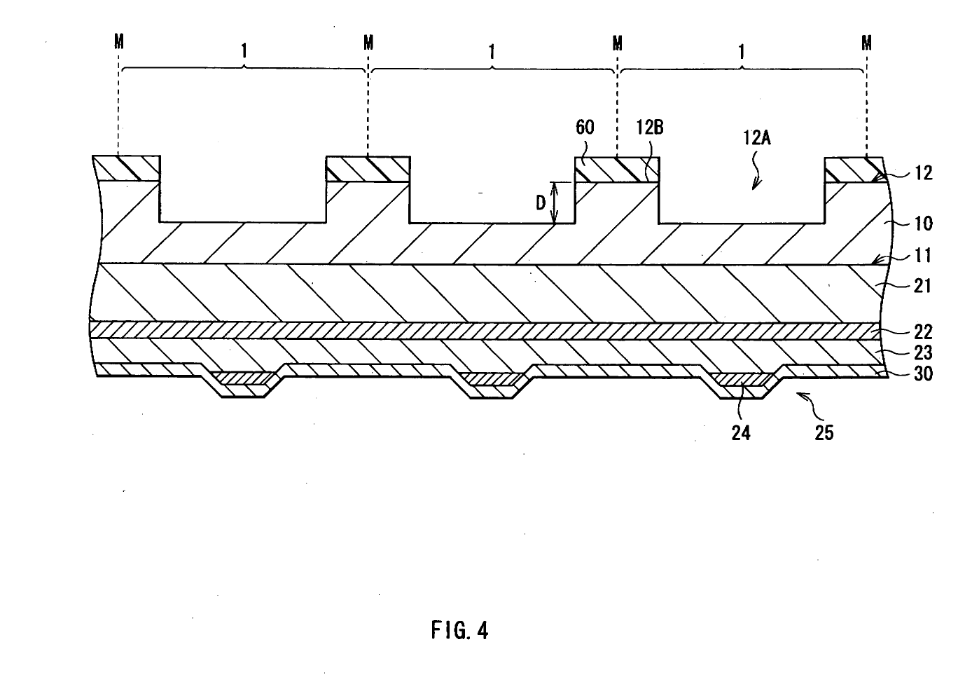

FIGS. 3 to 6 show steps in a method of manufacturing the laser diode according to the embodiment. At first, as shown in FIG. 3, for example, the substrate 10 made of the above-described material with the above-described thickness is prepared, and the n-type cladding layer 21, the active layer 22, the p-type cladding layer 23 and the p-side contact layer 24 are grown in order on the first surface 11 of the substrate 10 by, for example, MOCVD (Metal Organic Chemical Vapor Deposition).

Next, referring again to FIG. 3, a mask layer (not shown) made of, for example, a resist is formed on the p-side contact layer 24, and parts in a thickness direction of the p-side contact layer 24 and the p-type cladding layer 23 are selectively removed by dry etching using the mask layer so as to form the projection section 25.

Next, the insulating film made of the above-described material is formed on the p-side contact layer 24 and the p-type cladding layer 23 by, for example, evaporation or a CVD method, and an opening corresponding to the p-side contact layer 24 is formed in the insulating film. After that, referring again to FIG. 3, the p-side electrode 30 made of the above-described material is formed on surfaces of the p-side contact layer 24 and the insulating film by, for example, a vacuum evaporation method.

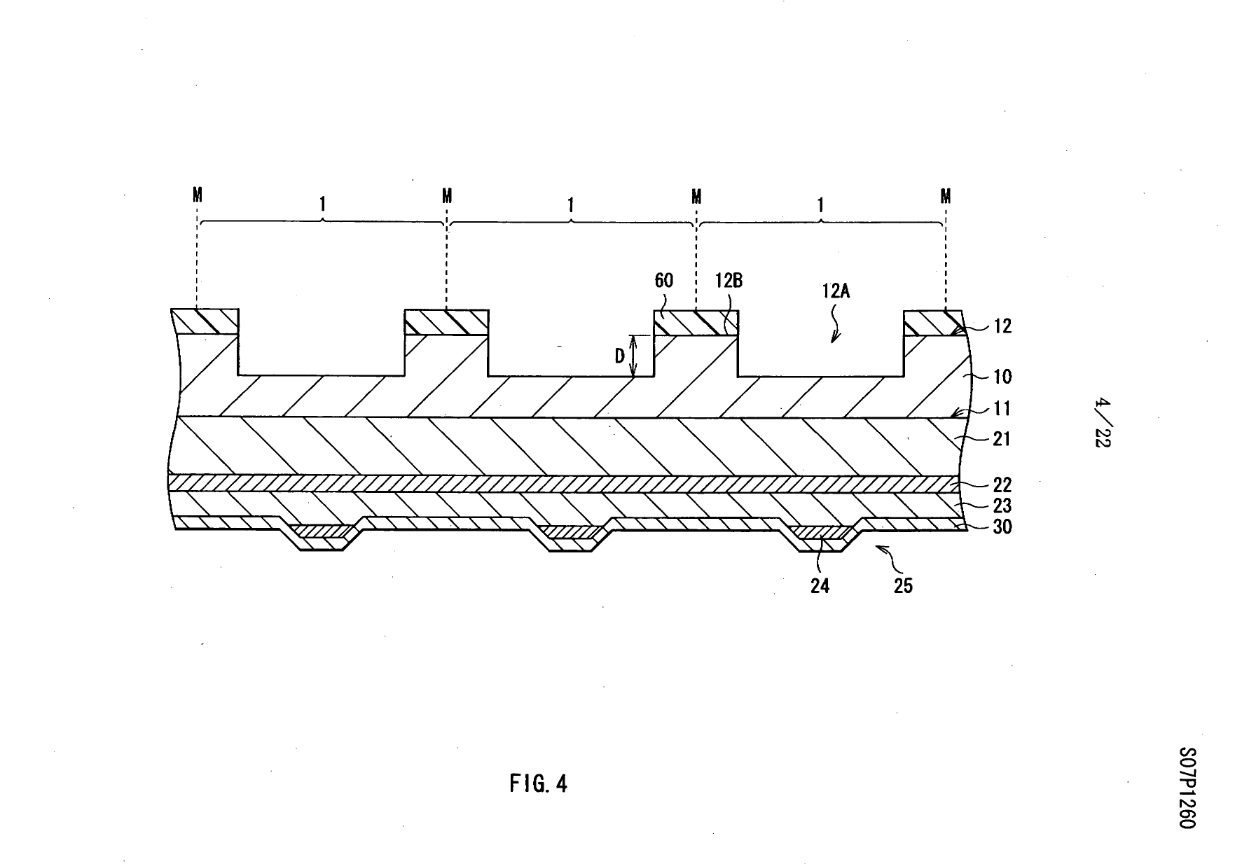

After the p-side electrode 30 is formed, as shown in FIG. 4, an etching protection film 60 made of a resist is formed on the second surface 12 of the substrate 10, and the recessed section 12A is formed on the second surface 12 by etching using the etching protection film 60 so as to form the step section 12B in a region other than the recessed section 12A, for example, a region close to the boundary line M of adjacent chip regions 1. At this time, the recessed section 12A is formed so that the depth D of the recessed section 12A is larger than the thickness T of the n-side electrode 40.

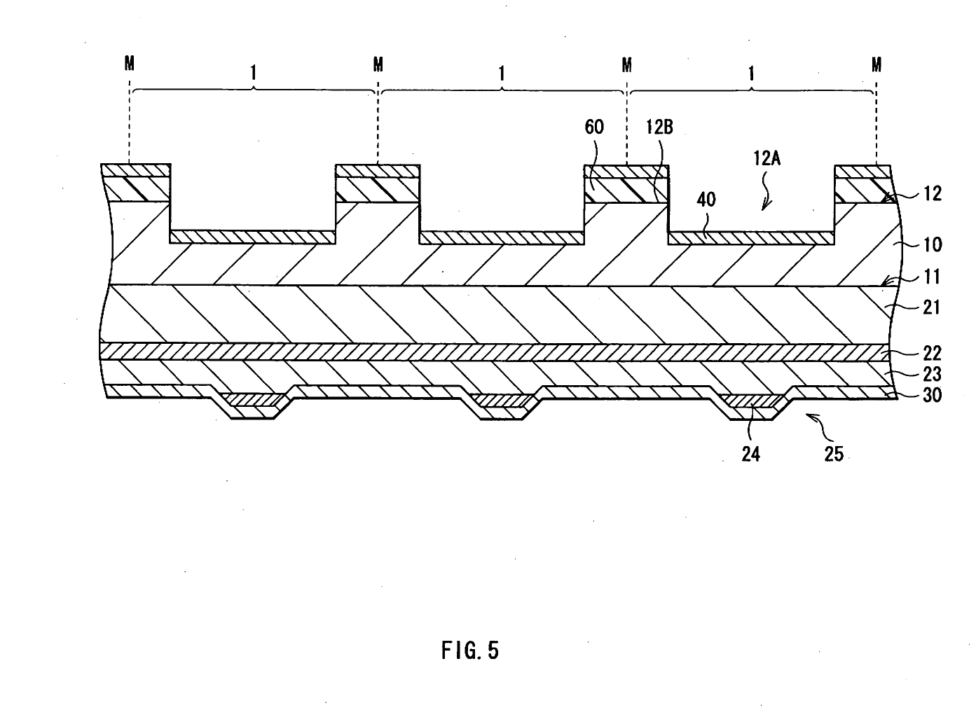

After the recessed section 12A is formed on the second surface 12, as shown in FIG. 5, the n-side electrode 40 made of the above-described material is formed on the whole second surface 12 by, for example, a vacuum evaporation method. After that, the etching protection film 60 is removed so as to form the n-side electrode 40 inside the recessed section 12A as shown in FIG. 1.

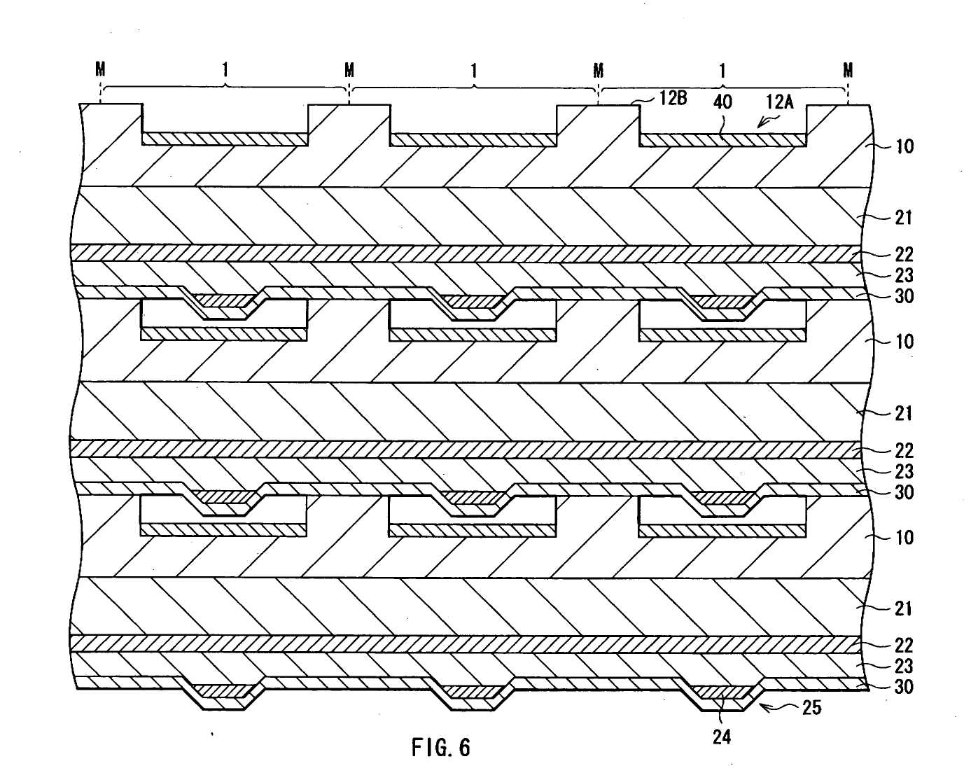

After the n-side electrode 40 is formed, the substrate 10 is cut by cleavage into a plurality of LD bars with a predetermined size. Next, as shown in FIG. 6, the LD bars are stacked so that the p-side electrode 30 and the n-side electrode 40 face each other, and then the coating films 50F and 50R are formed on the main-emission-side end surface 10F and the rear end surface 10R as cutting surfaces by, for example, an electron beam evaporation method. At this time, the n-side electrode 40 is formed inside the recessed section 12A, so the step section 12B as a spacer can prevent contact between the p-side electrode 30 and the n-side electrode 40. Therefore, fusion bonding between the p-side electrode 30 and the n-side electrode 40, damage to the p-side electrode 30 or the n-side electrode 40 or adhesion of contamination of the p-side electrode 30 or the n-side electrode 40 is prevented. Thus, the laser diode shown in FIGS. 1 and 2 is completed.

In the laser diode, when a predetermined voltage is applied between the n-side electrode 40 and the p-side electrode 30, a current is injected into the light-emitting region 22A of the active layer 22, thereby light is emitted by electron-hole recombination. The light is reflected by the coating films 50F and 50R as a pair of reflecting mirror films, and the light travels between the coating films 50F and 50R to cause laser oscillation, and the light is emitted to outside as a laser beam. In this case, the recessed section 12A for forming the n-side electrode 40 is arranged on the second surface 12 of the substrate 10, so an influence to laser characteristics due to arranging the recessed section 12A can be reduced to a very small level.

Thus, in the embodiment, the recessed section 12A with the depth D which is larger than the thickness T of the n-side electrode 40 is arranged on the second surface 12 of the substrate 10, and the n-side electrode 40 is formed inside the recessed section 12A, so in the case where the LD bars are stacked, the step section 12B acts as a spacer to prevent contact between the p-side electrode 30 and the n-side electrode 40, thereby fusion bonding between electrodes or damage to the electrodes can be prevented. Moreover, unlike related arts, when the LD bars are stacked, it is not necessary to insert a silicon (Si) chip between the LD bars, so manufacturing steps can be simplified, and workability can be improved. Further, the recessed section 12A for forming the n-side electrode 40 is arranged on the second surface 12 of the substrate 10, so an influence to laser characteristics due to arranging the recessed section 12A can be reduced to a very small level.

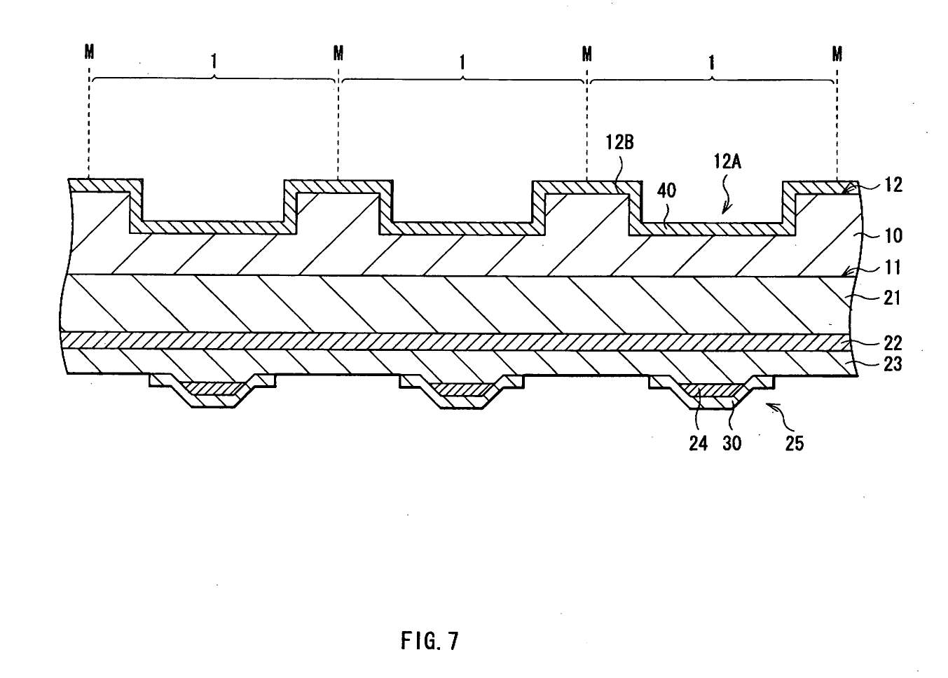

In the above-described embodiment, the case where the p-side electrode 30 is arranged on the whole surfaces of the p-side contact layer 24 and the insulating film, and the n-side electrode 40 is arranged on the bottom surface of the recessed section 12A is described; however, the planar shapes of the p-side electrode 30 and the n-side electrode 40 is not specifically limited as long as contact between the LD bars can be prevented in the case where the LD bars are stacked. For example, as shown in FIG. 7, while the p-side electrode 30 is arranged only on the projection section 25 corresponding to the light-emitting region 22A, the n-side electrode 40 may be arranged on the whole second surface 12.

Moreover, in the above-described embodiment, the case where the step section 12B is arranged on the boundary line M of adjacent chip regions 1 is described; however, the degree of freedom of the planar shapes or the positions of the recessed section 12A and the step section 12B is high, and the planar shapes or the positions of the recessed section 12A and the step section 12B are not limited to the case of the above-described embodiment. Modifications in which the planar shapes of the recessed section 12A and the step section 12B are different will be described below.

(Modification 1)

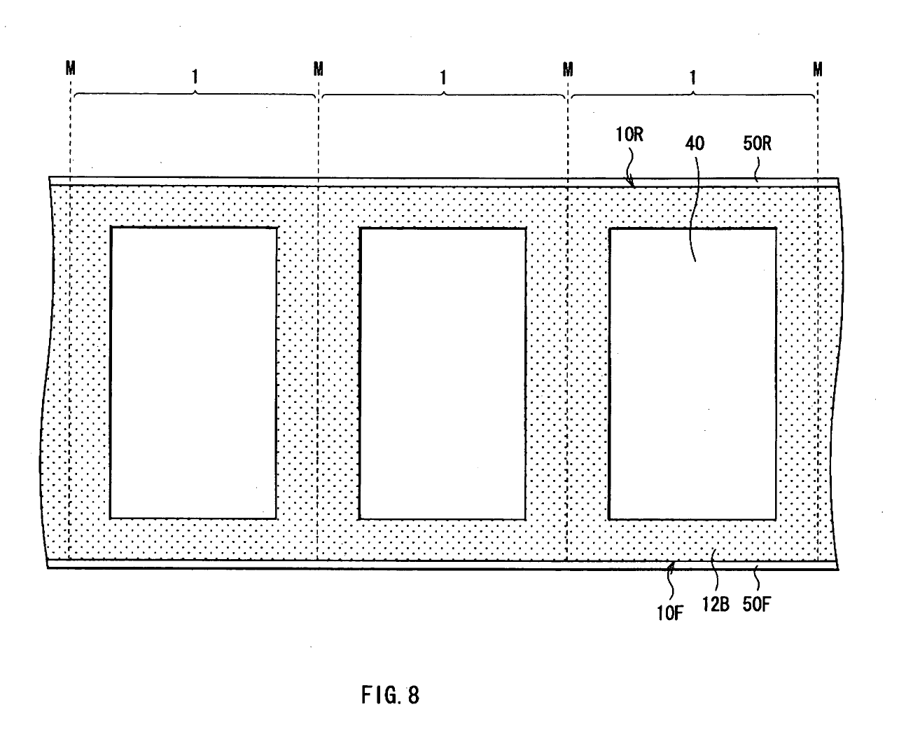

FIG. 8 is a plan view showing the configuration of a laser diode according to Modification 1 of the invention. The laser diode has the same configuration, functions and effects as those in the above-described embodiment, except that the step section 12B is arranged on the boundary line M of adjacent chip regions 1, the main-emission-side end surface 10F and the rear end surface 10R, and the laser diode can be manufactured in the same manner as in the above-described embodiment. Further, in the modification, when the substrate 10 is cut by cleavage to form the main-emission-side end surface 10F and the rear end surface 10R, the thickness of the substrate 10 on a cleavage line is the same, so the substrate 10 can be easily cut.

(Modification 2)

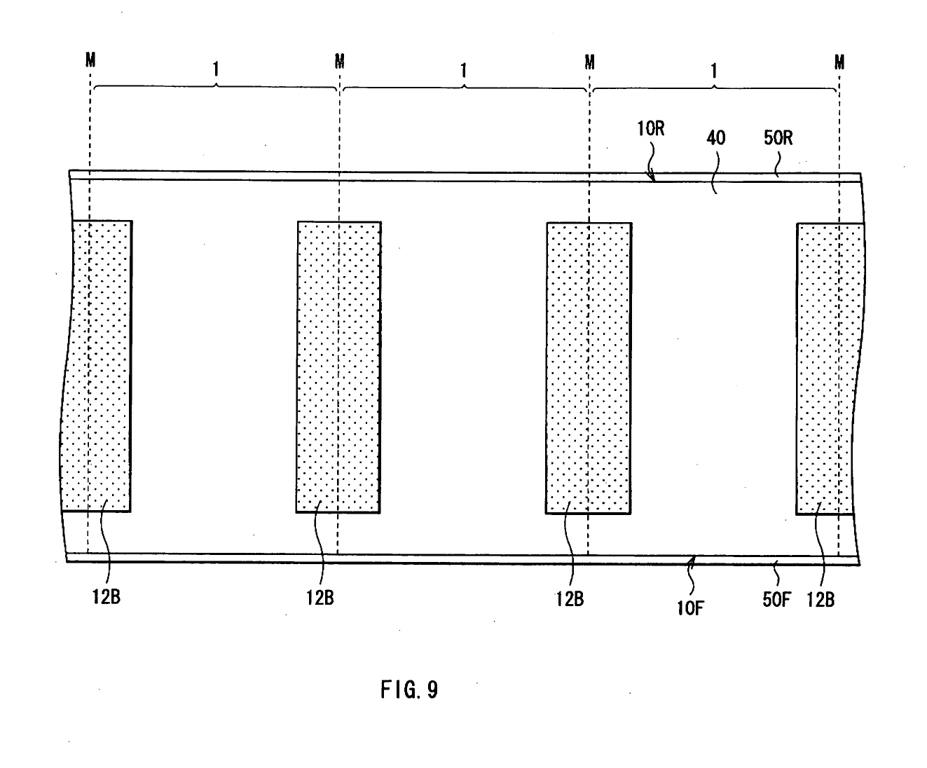

In the modification, as shown in FIG. 9, the step section 12B is not arranged on both ends of the boundary line M of adjacent chip regions 1, that is, near the main-emission-side end surface 10F and the rear end surface 10R. Even in this case, like Modification 1, when the substrate 10 is cut by cleavage to form the main-emission-side end surface 10F and the rear end surface 10R, the thickness of the substrate on the cleavage line is the same, so the substrate 10 can be easily cut.

(Modification 3)

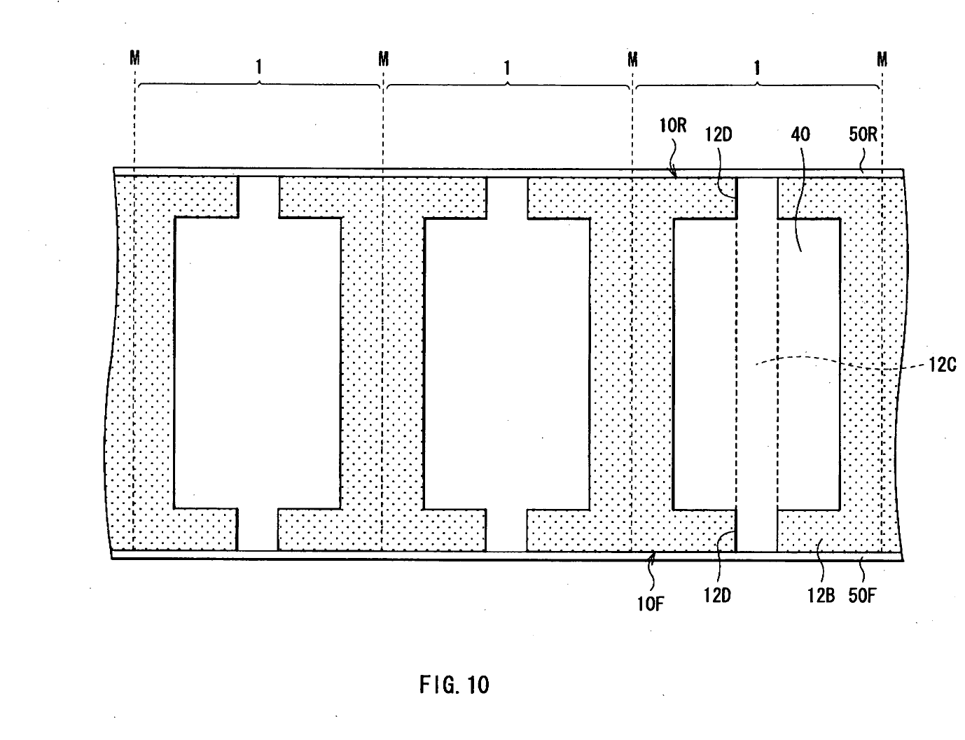

FIG. 10 shows a plan view of a laser diode according to Modification 3. The laser diode in the modification is the same as that in Modification 1, except that a notch 12D is arranged in the step section 12B so that the step section 12B is not arranged on a region 12C facing the light-emitting region 22A in the second surface 12. Thereby, the p-side electrode 30 on the projection section 25 can be prevented from being damaged by contact with the step section 12B.

(Modification 4)

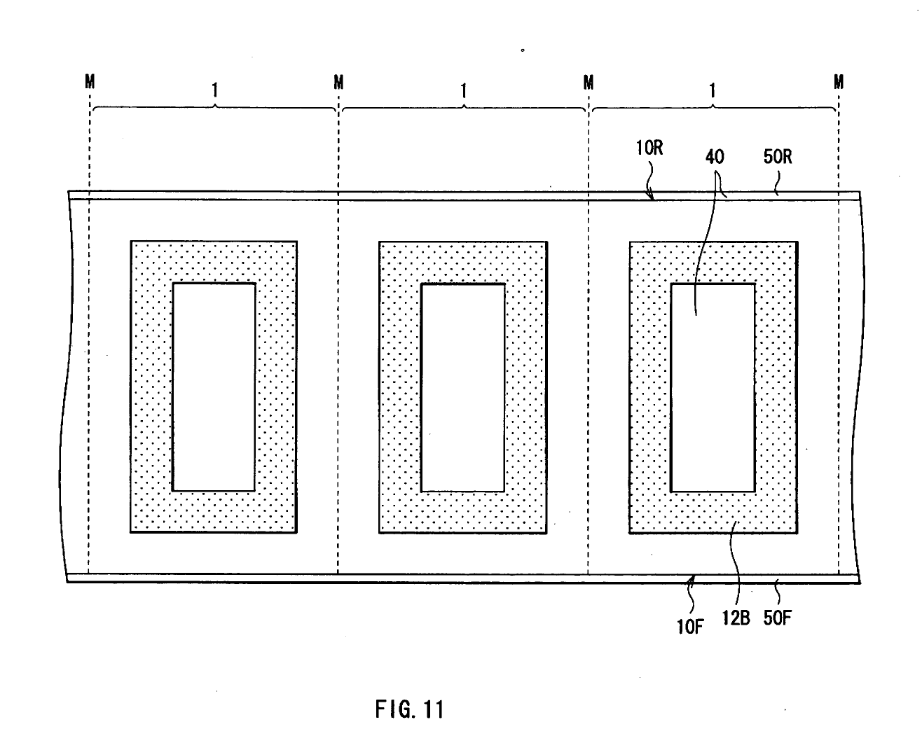

FIG. 11 shows a plan view of a laser diode according to Modification 4 of the invention. In the laser diode, the step section 12B is arranged inside the boundary line M of adjacent chip regions 1, the main-emission-side end surface 10F and the rear end surface 10R in a frame form. This configuration is preferable specifically in the case where after forming LD bars by cleavage, the LD bars are further cut along the boundary line M of adjacent chip regions 1 so as to be separated into individual LD chips. It is because the thickness of the substrate 10 on the boundary line M is the same, so the substrate 10 can be easily cut.

(Modification 5)

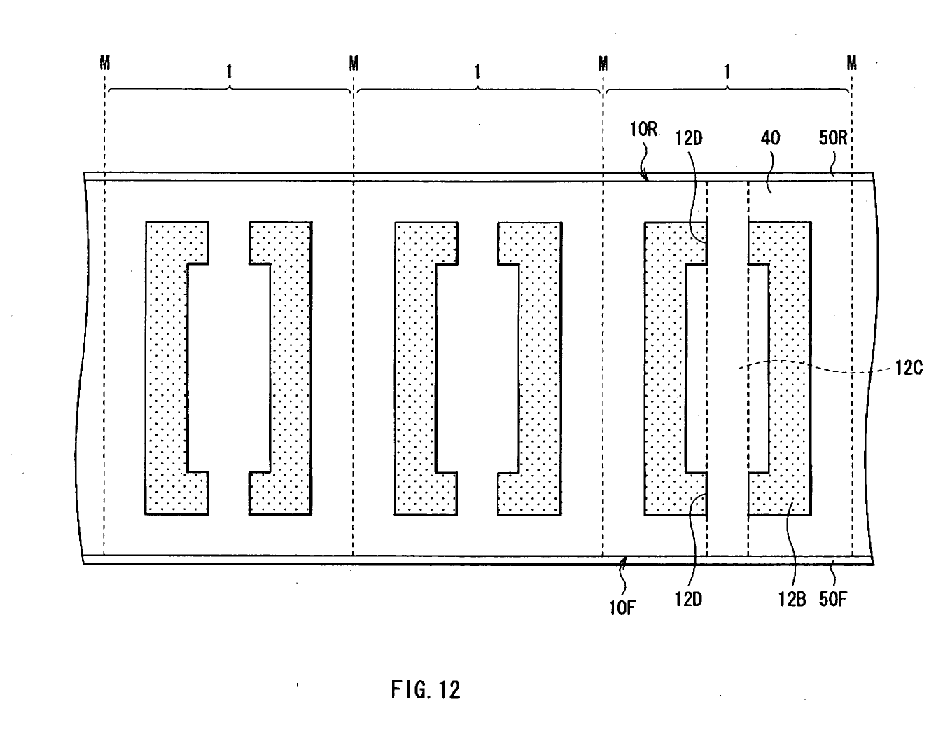

Modification 5 shown in FIG. 12 is the same as Modification 4, except that as in the case of Modification 3, the notch 12D is arranged in the step section 12B on each of the main-emission-side end surface 10F side and the rear end surface 10R side so that the step section 12B is not arranged on the region 12C facing the light-emitting region 22A in the second surface 12. By the modification, the same effects as those in Modifications 3 and 4 can be obtained.

(Modification 6)

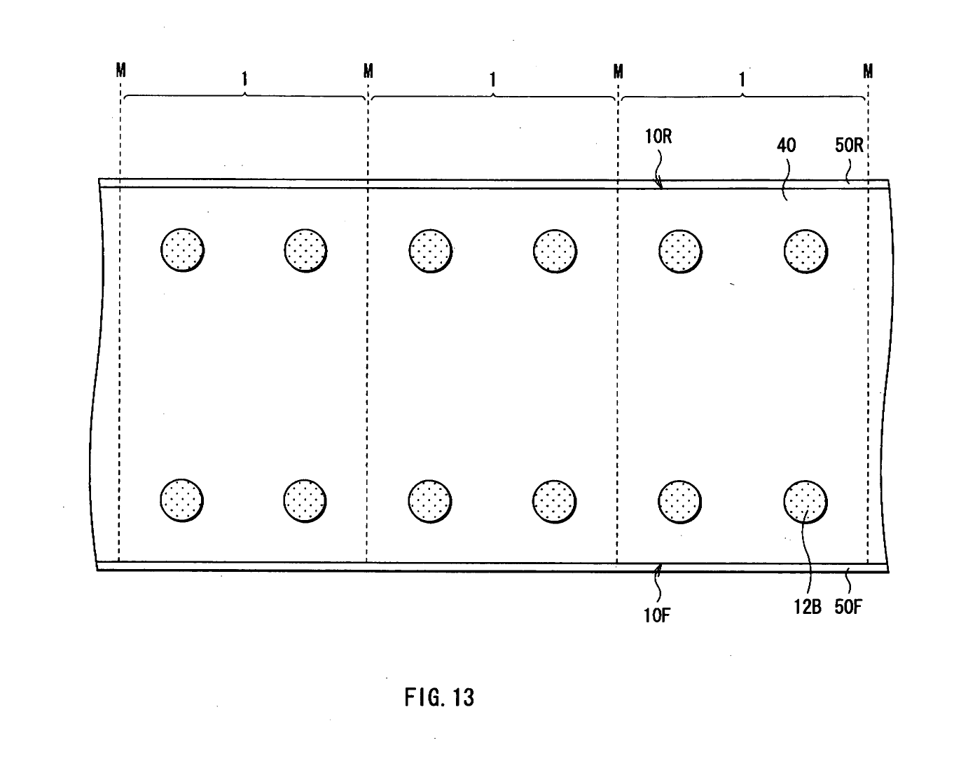

Further, as an application of Modification 5, as shown in FIG. 13, the step sections 12B may be dotted inside the boundary line M of adjacent chip regions 1, the main-emission-side end surface 10F and the rear end surface 10R. In this case, the shape of the step section 12B is not limited to a circular shape, and may be a rectangular shape or a hook shape. Moreover, the number of the step sections 12B is not limited to four, and the step sections 12B are not necessarily arranged in four corners.

### Second Embodiment

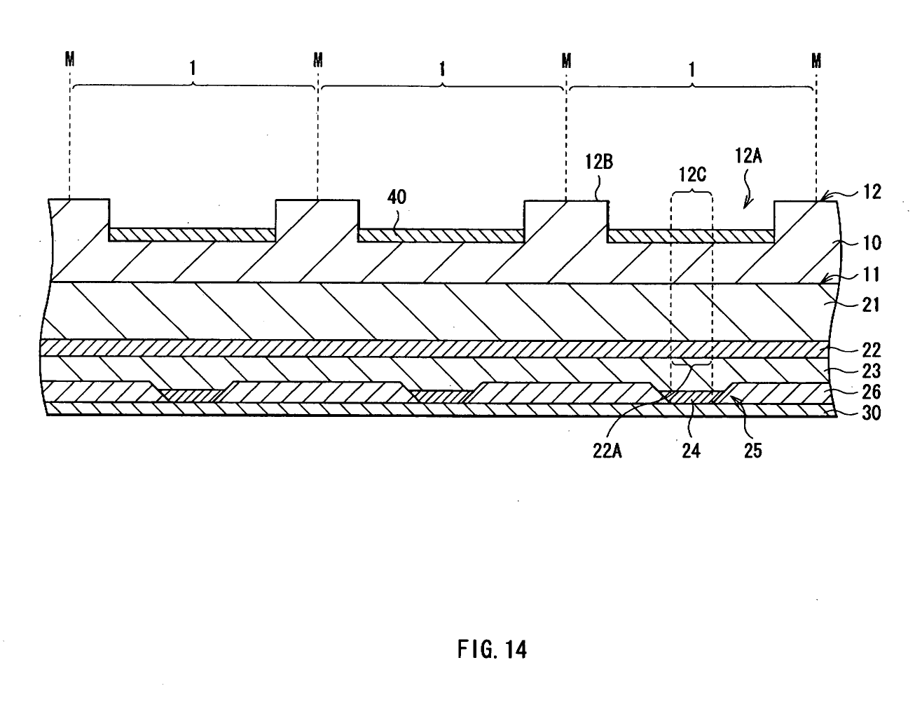

FIG. 14 shows the configuration of a laser diode according to a second embodiment of the invention. The laser diode has the same configuration as that in the first embodiment, except that regions on both sides of the projection section 25 are filled with current confinement layers 26. Therefore, like components are denoted by like numerals as of the first embodiment.

The n-type cladding layer 21, the active layer 22, the p-type cladding layer 23, the p-side contract layer 24 and the p-side electrode 30 on the first surface 11 of the substrate 10 are formed by the same manner as that in the first embodiment. The current confinement layer 26 is made of, for example, n-type GaAs doped with an n-type impurity such as silicon or selenium.

The recessed section 12A and the step section 12B are formed on the second surface 12 of the substrate 10 as in the case of the first embodiment, and the n-side electrode 40 is formed inside the recessed section 12A. As in the case of the first embodiment, the depth D of the recessed section 12A is larger than the thickness T of the n-side electrode 40, and the depth D is preferably larger than the total of the thickness T of the n-side electrode 40 and the height H of a step formed by the projection section 25 and the p-side electrode 30. However, in the embodiment, the current confinement layers 26 are arranged on both sides of the projection section 25, and the height H is reduced, so in many cases, it is sufficient that the depth D of the recessed section 12A is larger than the thickness T of the n-side electrode 40. Moreover, as in the case of the first embodiment, the width W of the recessed section 12A is preferably larger than the width W25 of the projection section 25.

As in the case of the first embodiment, the step section 12B is preferably arranged, for example, on the boundary line M of adjacent chip regions 1 and not on the region 12C facing the light-emitting region 22A in the second surface 12. It is because in the case where the LD bars are stacked, the p-side electrode 30 on the light-emitting region 22A can be prevented from being damaged by contact with the step section 12B.

The n-side electrode 40 and the coating films 5OF and 5OR are formed by the same manner as in the first embodiment.

The laser diode can be manufactured by the same manner as that in the first embodiment, except that after the projection section 25 is formed using a mask layer (not shown) made of, for example, silicon dioxide, the current confinement layers 26 are formed on both sides of the projection section 25 by selective epitaxial growth using the same mask layer, and functions and effects in the embodiment are the same as those in the first embodiment.

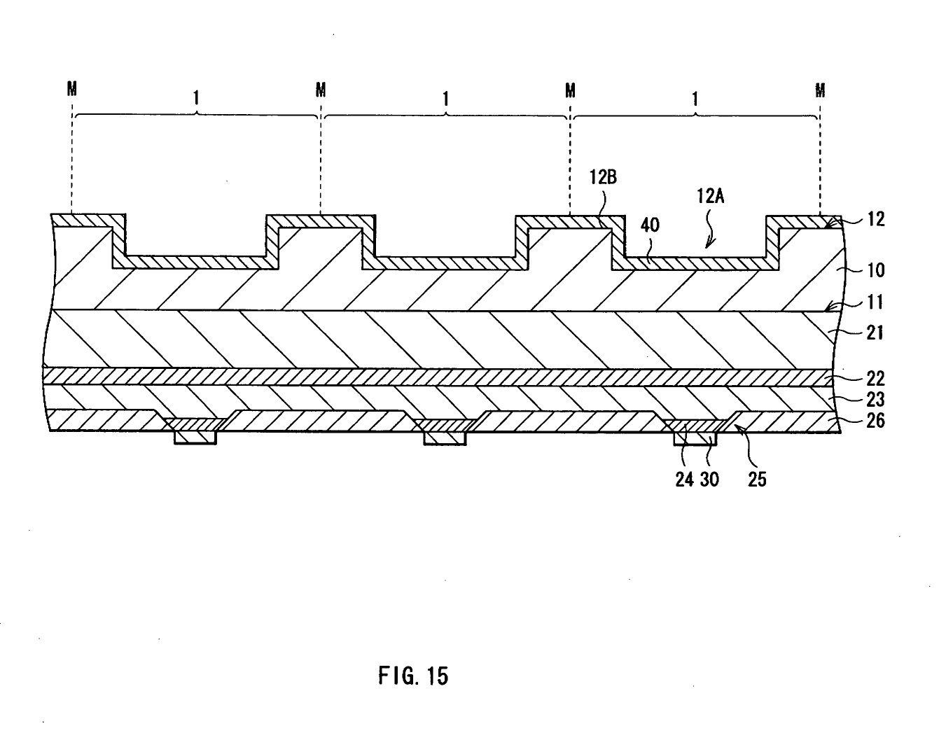

In the embodiment, as shown in FIG. 15, while the p-side electrode 30 is arranged only on the projection section 25, the n-side electrode 40 may be arranged on the whole second surface 12. In this case, the depth D of the recessed section 12A is preferably larger than the total thickness of the n-side electrode 40 and the p-side electrode 30.

### Third Embodiment

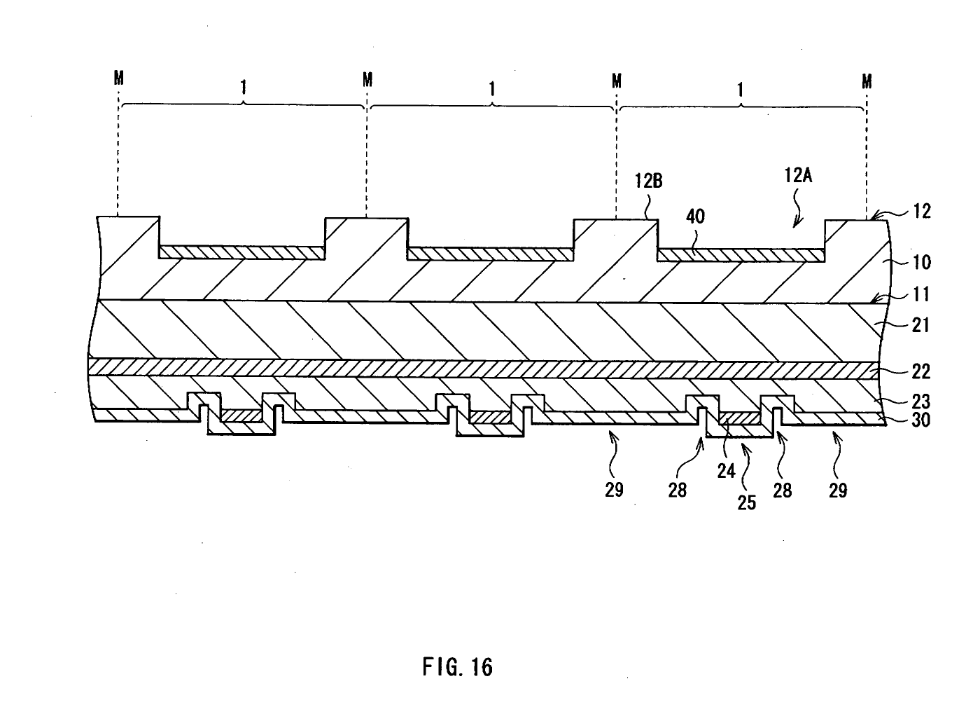

FIG. 16 shows the configuration of a laser diode according to a third embodiment of the invention. The laser diode has the same configuration as that in the first embodiment, except that the laser diode has a so-called double ridge configuration in which outer projection sections 29 with a slightly lower height are formed on both sides of the projection section 25 with two parallel grooves 28 in between, and functions and effects in the embodiment are the same as those in the first embodiment.

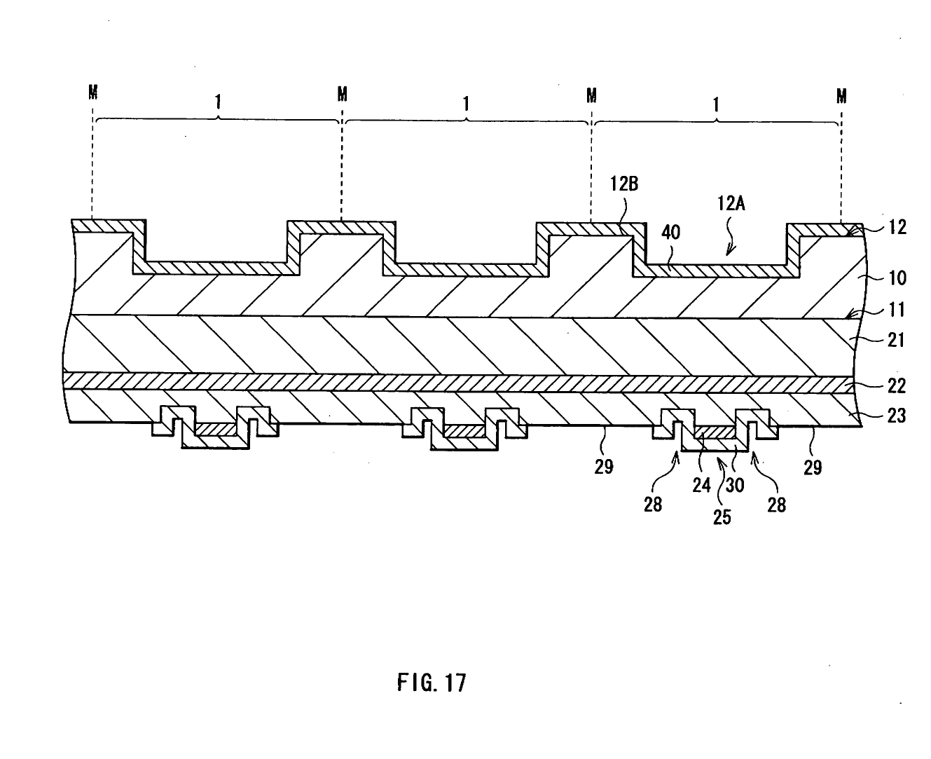

In the embodiment, as shown in FIG. 17, while the p-side electrode 30 is arranged only on the projection section 25 in the middle and not on the outer projection sections 29, the n-side electrode 40 may be arranged on the whole second surface 12.

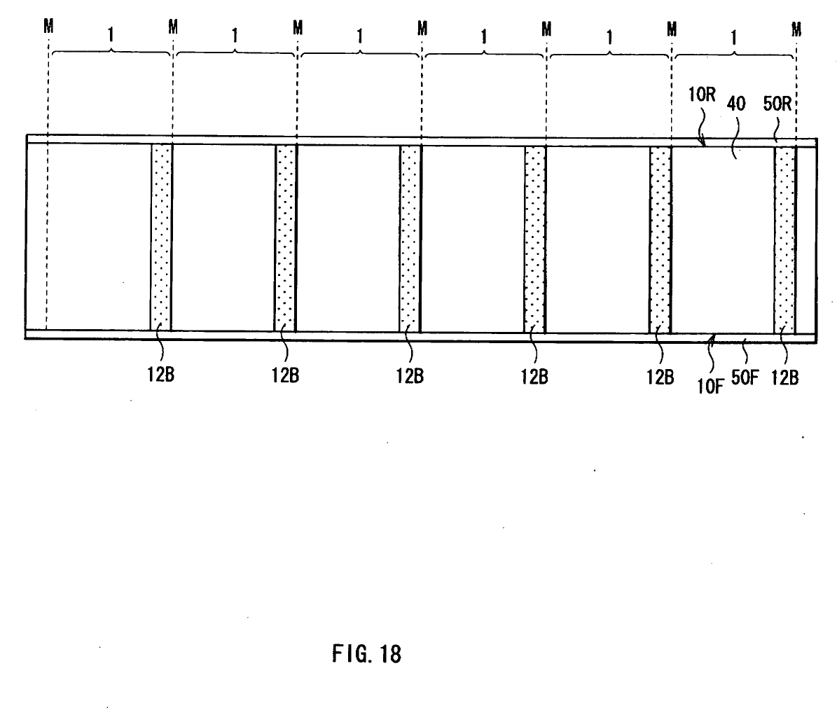

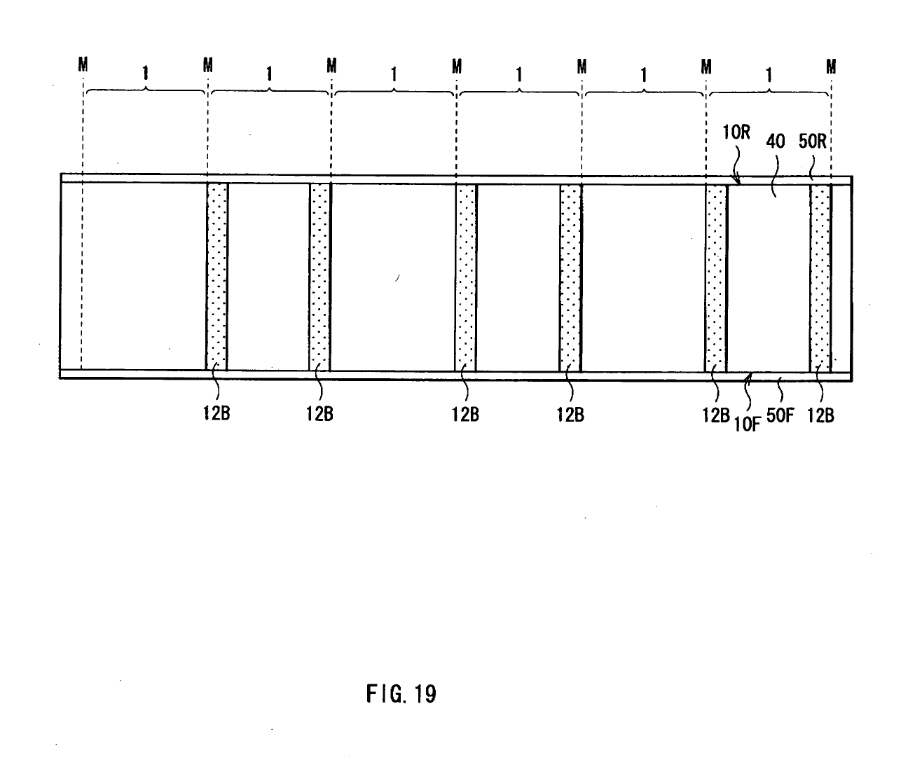

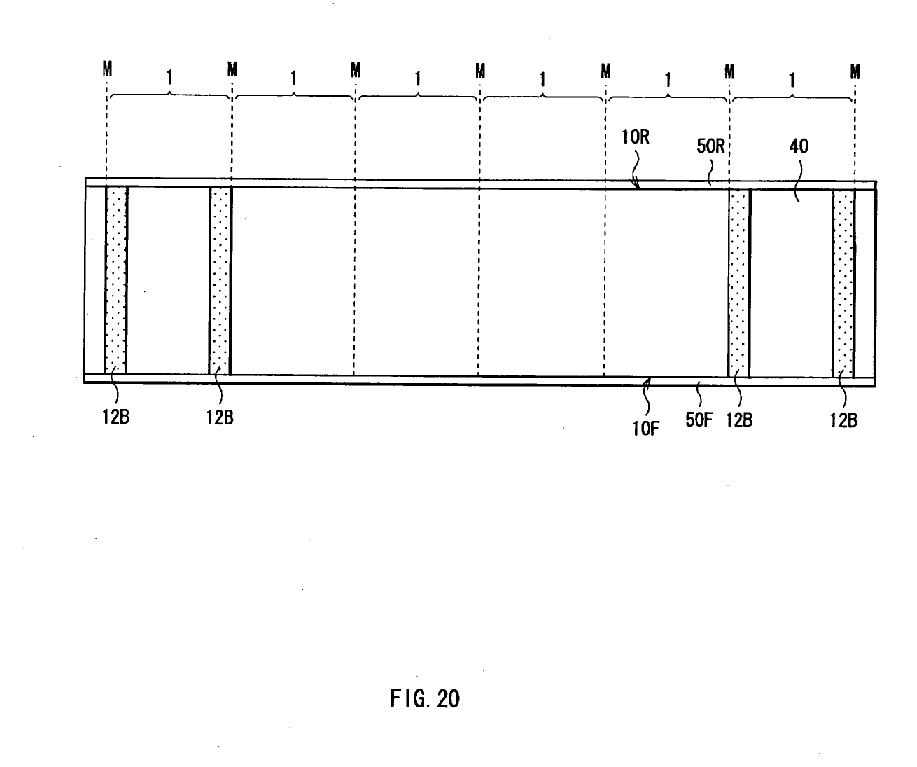

Although the present invention is described referring to the embodiments, the invention is not limited to the embodiments, and can be variously modified. For example, in the above-described embodiments, the case where the step section 12B is arranged on both sides of the boundary lines M of adjacent chip regions 1 is described; however, as shown in FIG. 18, the step section 12B may be arranged on only one side of the boundary line M. Moreover, the step section 12B is not necessarily arranged on all chip regions 1. For example, as shown in FIG. 19, the step section 12B may be arranged on every other chip region 1, or as shown in FIG. 20, the step sections 12B may be arranged only on the chip regions 1 positioned on both ends of a LD bar.

Moreover, for example, the material, the thickness, the forming method and the forming conditions of each layer described in the above embodiments are not limited to those described above, and the layer may be made of any other material with any other thickness, and the layer may be formed by any other forming method under any other forming conditions. For example, the material of the active layer 22 may be any other Group III-V compound semiconductor such as AlGaInP mixed crystal. As a Group III element, at least one kind selected from the group consisting of aluminum (Al), gallium (Ga) and indium (In) is cited, and as a Group V element, at least one kind selected from the group consisting of nitrogen (N), phosphorus (P) and arsenic (As) is cited.

Further, for example, in the above embodiments, a red laser including a semiconductor layer made of an AlGaInP-based compound semiconductor on the substrate 10 made of GaAs is described as an example; however, the invention is applicable to a laser including a semiconductor layer made of any other material based-semiconductor such as a GaAs-based semiconductor (infrared: 780 nm to 850 nm) or a GaN-baed semiconductor (oscillation wavelength typically from 400 nm to 500 nm). Moreover, the substrate 10 may be made of GaN or GaP.

In addition, in the above embodiments, the laser diode having the configuration in which the n-type semiconductor layer, the active layer and the p-type semiconductor layer are laminated in order on the n-type substrate 10 is described; however, the laser diode may have a reverse conductive type configuration in which a p-type substrate is used, and a p-type semiconductor layer, an active layer and an n-type semiconductor layer are laminated on the p-type substrate.

For example, in the above embodiments, the configuration of the laser diode is described referring to specific examples; however, the laser diode does not necessarily include all layers, or may further include any other layer. For example, guide layers for optical confinement may be arranged between the n-type cladding layer 21 and active layer 22 and between the active layer 22 and the p-type cladding layer 23.

The invention is applicable to not only a refractive index-guiding type laser diode including the projection section 25 described in the above embodiments but also a gain-guiding type laser diode.

Moreover, Modifications 1 to 6 are applicable to the laser diodes according to the second embodiment and the third embodiment.

Further, the invention is applicable to not only laser diodes but also semiconductor light-emitting devices including a coating film on an end surface formed by cutting a substrate such as LEDs (Light Emitting Diodes), and the invention is applicable to methods of manufacturing the semiconductor light-emitting devices.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor light-emitting device comprising a semiconductor layer and a first electrode on a first surface of a semiconductor substrate in order from the semiconductor substrate side and a second electrode on a second surface of the semiconductor substrate, the semiconductor layer including a light-emitting region, the first electrode being arranged corresponding to at least the light-emitting region,
wherein a recessed section with a depth larger than the thickness of the second electrode is arranged on the second surface, thereby a step section projected from the recessed section is formed in a region other than the recessed section in the second surface, and
the second electrode is formed on at least the recessed section of the second surface.

2. The semiconductor light-emitting device according to claim 1, wherein
the step section is not arranged in a region facing the light-emitting region in the second surface.

3. The semiconductor light-emitting device according to claim 1, wherein
the second electrode is formed on the bottom surface of the recessed section, and the first electrode is formed on the whole surface of the semiconductor layer.

4. The semiconductor light-emitting device according to claim 1, wherein
the second electrode is formed on the whole second surface, and the first electrode is formed corresponding to the light-emitting region of the semiconductor layer.

5. The semiconductor light-emitting device according to claim 1, wherein
the semiconductor layer includes a projection section in a region corresponding to the light-emitting region.

6. The semiconductor light-emitting device according to claim 5, wherein
the depth of the recessed section is larger than the total of the thickness of the first electrode, the thickness of the second electrode and the height of the projection section.

7. The semiconductor light-emitting device according to claim 5, wherein
the step section is arranged in a region other than a region facing the projection section in the second surface.

8. The semiconductor light-emitting device according to claim 1, wherein
the light-emitting region emits laser light by current injection from the first electrode and the second electrode.

9. A method of manufacturing a semiconductor light-emitting device, the semiconductor light-emitting device including a semiconductor layer and a first electrode on a first surface of a semiconductor substrate and a second electrode on a second surface of the semiconductor substrate, the semiconductor layer including a light-emitting region, the method comprising the steps of:
after forming the semiconductor layer on the first surface, forming the first electrode on the first surface so as to correspond to at least the light-emitting region;
arranging a recessed section with a depth larger than the thickness of the second electrode on the second surface so as to form a step section projected from the recessed section in a region other than the recessed section in the second surface;
forming the second electrode on at least the recessed section of the second surface;
forming a plurality of bars by cutting the semiconductor substrate; and
stacking the plurality of bars so that the first electrode and the second electrode face each other, and forming a coating film on a cutting surface.

10. The method of manufacturing a semiconductor light-emitting device according to claim 9, wherein
the step section is not arranged on a region facing the light-emitting region in the second surface.

11. The method of manufacturing a semiconductor light-emitting device according to claim 9, wherein
when the semiconductor layer is formed on the first surface, a projection section is formed in a region corresponding to the light-emitting region in the semiconductor layer,
a recessed section with a depth larger than the total of the thickness of the first electrode, the thickness of the second electrode and the height of the projection section is formed on the second surface, and
the plurality of bars are stacked so that the projection section is set in the recessed section.

12. The method of manufacturing a semiconductor light-emitting device according to claim 9, wherein
the light-emitting region has a strip shape, and
the semiconductor substrate is cut on a surface intersecting an extending direction of the light-emitting region so as to form a plurality of bars.
